(19) United States
(12) Patent Application Publication
(10) Pub. No.: US 2025/0122380 A1
(43) Pub. Date: Apr. 17, 2025

(54) RADAR TRANSPARENT, OPTICALLY REFLECTIVE SEMICONDUCTOR EFFECT PIGMENTS

(71) Applicant: ECKART America Corporation, Painesville, OH (US)

(72) Inventors: Devin Schmitt, Munster, IN (US); Christopher Hilbrich, Crown Point, IN (US); Jonglak Choi, Munster, IN (US)

(21) Appl. No.: 18/688,861

(22) PCT Filed: Sep. 29, 2022
(86) PCT No.: PCT/IB2022/059270

§ 371 Date: Mar. 4, 2024

Related U.S. Application Data
(60) Provisional application No. 63/280,853, filed on Nov. 18, 2021.

(30) Foreign Application Priority Data
Nov. 26, 2021 (EP) 21210904.5

(51) Int. Cl. C09C 1/00; C09D 5/03

(52) U.S. Cl. CPC C09C 1/0069; C09D 5/031; C09C 2200/301; C09C 2200/407; C09C 2200/505

(57) ABSTRACT

This invention deal with a flaky effect pigment comprising as optical active layer a single platelet consisting of a semiconductor material with a band gap in a range of 0.1 to 2.5 eV and having an average atomic composition of: a) Si₍₁₋ₓ₎Geₓ, wherein 0<x<1.00 or b) Si_{(1-y)}Sn_{y}, wherein 0<y<0.90 or c) Ge_{(1-z)}Sn₂, wherein 0<z≤0.60 or d) Si₍₁₋ₘ₋ₙ₎GeₘSnₙ, wherein 0<m<1.00, 0<n<1.00 with the provisos that x<1.00; y<1.00, z<1.00 and m+n<1.00. These effect pigments exhibit attractive optical properties and are radartransparent.

The present invention relates to effect pigments based on certain semiconductor platelets as the only optically active layer, a method for their production and use as radar transparent effect pigment with attractive optical properties.

Aluminum obtains high surface reflectivity from its high electrical conductivity, leading to a high surface plasma frequency. Provided that the frequency of light incident upon the surface is below the surface plasma frequency, incident light will efficiently reflect from the surface. In aluminum, the surface plasma frequency can reflect light wavelengths ≥ near UV light including visible, IR, microwave, and radio. Thus, aluminum, and most metals, show high reflectivity over a broad range of wavelengths. Unfortunately, the same effect that governs visible light reflection also is effective at reflecting IR, microwave, and RADAR wavelengths. Platelets of aluminum and other metals, therefore, have insufficient RADAR transparency, but are at the same time used worldwide as standard effect pigment for metallic effects in the visible range, especially in automotive coatings.

Dielectrics like pearlescent pigments have been utilized in conjunction with fine aluminum flakes to increase the RADAR transparency of the composite as disclosed in WO 2020/208134 A1, US 2010/0022696 A1 or WO 2021/030197 A1.

Here metal flakes and typically aluminum flakes are still present in the coating and the radar attenuation needs to be balanced with the envisioned optical properties of the final coating. In many cases the radar attenuation is still too high and/or certain color tones cannot be realized.

US 2002/0041047 A1 focusses on an efficient method of production of thin metal flakes by a PVD process. It mainly deals with aluminum flakes but also discloses in one example a Si flake with a thickness of 35 nm.

Dielectrics are non-electrically conductive and, therefore, do not suffer from the same high surface plasma frequency reflectivity of aluminum. Dielectrics achieve reflectivity and opacity through Fresnel reflection, where the reflectance equation of the top single surface is defined as:

$${r}_{t o p} = ( {n}_{m a t} - {n}_{m e d 1} ) / ( {n}_{m a t} + {n}_{m e d 1} )$$

and the reflectance equation of the bottom surface (as referenced from above incident light) is defined as:

$${r}_{b o t t o m} = ( {n}_{m e d 2} - {n}_{m a t} ) / ( {n}_{m e d 2} + {n}_{m a t} )$$

where rₜₒₚ is the reflectance amplitude from the top surface, r_{bottom} is the reflectance amplitude from the bottom surface, nₘₐₜ is the refractive index of the material, n_{med1} is the refractive index of the medium above the material and n_{med2} is the refractive index of the medium below the material (incident light above n_{med1}).

The reflectance intensity (R) is defined as R=r².

In a binder system, it can typically be assumed that 1.35<n_{med1}=n_{med2}<1.6. As dielectric materials, such as TiO₂ and SiO₂, typically display n_{dielectric}≤2.7, the upper limit of the total reflectivity from both surfaces (assuming constructive interference) is <25%. Thus, while dielectric pigments display high RADAR transparency when homogenized to particle size<<I_{RADAR}, their utility is limited due to low optical reflectivity and low opacity (hiding power).

Semiconductors typically display high nₘₐₜ throughout the spectral range with an enhanced nₘₐₜ above the band gap. For instance, silicon displays an nₛₑₘᵢ of ˜3.4 at λ˜4000 nm with an apex nₛₑₘᵢ of ˜6.7 at λ˜370 nm. This relationship holds true for most elemental and compound semiconductors. Using the same conditions as the above mentioned dielectrics (assuming 1.35<n_{med1}=n_{med2}<1.6) but with a nₛₑₘᵢ of ˜5.0 in the visible range, the total reflectivity can achieve>50% (assuming constructive interference).

The use of semiconductor films like silicon, germanium or alloys thereof are known in literature for the fabrication of random systems for the development of self-driving cars. Examples thereof are disclosed in WO 2021/018422 A1 or US 2010/0207842 A1.

However there is an urgent need to develop also effect pigments to enable the coating industry to offer coating formulations and paints with a wide optical versatility and effects and at the same time with sufficient radar transparency.

Particularly there is a need for new effect pigments which have a metallic look but are much more radar transparent than mixtures of metallic effect pigments with dielectric pigments. They should be easily accessible and have different color tones. A special desire is directed to silvery looking effect pigments as these do have the highest attractiveness especially in the automotive market.

The pigments should have a good hiding power, metallic gloss and a high metallic flop.

These objects are solved by providing a flaky effect pigment comprising as optical active layer a single platelet consisting of a semiconductor material with a band gap in a range of 0.1 to 2.5 eV and having an average atomic composition of:
a) Si₍₁₋ₓ₎Geₓ, wherein 0<x<1.00 or
b) Si_{(1-y)}Sn_{y}, wherein 0<y<0.90 or
c) Ge_{(1-z)}Sn_{z}, wherein 0<z≤0.60 or
d) Si₍₁₋ₘ₋ₙ₎GeₘSnₙ, wherein 0<m<1.00, 0<n<1.00
with the provisos that x<1.00; y<1.00, z<1.00 and m+n<1.00.

Further preferred embodiments are disclosed in claims 2 to 11.

The object is further solved by providing a method of manufacture of the effect pigments comprising the steps:
a) providing a flexible substrate coated with a release agent,
b) evaporating under ultra high vacuum conditions a semiconductor material with a band gap in a range of 0.1 to 2.5 eV onto the flexible substrate a),
c) stripping the semiconductor film from the flexible substrate in a suitable solvent and comminuting the particles in the dispersion to obtain semiconductor flakes,
d) separating the semiconductor flakes from the solvent and
e) optionally conducting further steps like any of further size classifying the semiconductor flakes or dispersing the semiconductor flakes in a different solvent and further surface treatment steps.

Further preferred embodiments are disclosed in claims 13 to 14.

Finally the object of the present invention is solved by providing coating systems comprising a binder and the flaky effect pigments.

In this invention the single platelet semiconductor has an average atomic composition of:
a) Si₍₁₋ₓ₎Geₓ, wherein 0<x<1.00 or
b) Si_{(1-y)}Sn_{y}, wherein 0<y<0.90 or
c) Ge_{(1-z)}Sn_{z}, wherein 0<z≤0.60 or
d) Si₍₁₋ₘ₋ₙ₎GeₘSnₙ, wherein 0<m<1.00 and 0<n<1.00 and
with the provisos that x<1.00; y<1.00, z<1.00 and m+n<1.00.

The x, y, n and m are mole fractions. In further preferred embodiments the single platelet semiconductor according to a) has a composition of 0.01<x<0.9, more preferably 0.02≤x≤0.8 and most preferably 0.05≤x≤0.65. These materials are alloys of silicon and germanium. Germanium adds interesting color effects as this material is absorbing in the visible wavelength region. This also enhances the opacity compared to pure silicon flakes. Due to the high costs of this material the content of germanium is preferably as low as possible.

In further preferred embodiments the single platelet semiconductor according to b) has a composition of 0.02≤y≤0.75 and more preferred of 0.05≤y≤0.55. These materials are alloys of silicon and tin.

In further preferred embodiments the single platelet semiconductor according to c) has a composition of 0.02≤z≤0.5 and more preferred a composition of 0.05≤z≤0.4. These materials are alloys of germanium and tin.

In further preferred embodiments the single platelet semiconductor according to d) has a composition characterized by 0.02≤m≤0.8 and 0.02≤n≤0.75 and more preferred a composition characterized by 0.05≤m≤0.65, 0.05≤n≤0.55.

The platelet semiconductor particles may further contain usual impurities occurring by the manufacture of the materials such as carbon, nitrogen or oxygen. These materials are not included into the formulas mentioned above.

Impurities of other metals or other semiconductor materials not contained into the formulas above are typically less than 0.1 wt.-%, preferably less than 0.05 wt.-%, more preferably less than 0.005 wt.-% of the platelet semiconductor material and are also not included into the formulas above.

The platelet semiconductor particles may further contain some amounts of oxygen due to surface oxidation. For example, a platelet alloy semiconductor flake may be oxidized on it's surface. This kind of oxygen is also not included in the formulas for the sake of clarity. Preferably the platelet semiconductor particles do not contain any noticeable amount of oxygen in their interior.

In a preferred embodiment the band gap of the flaky effect pigment is in a range of 0.2 to 1.4 eV and more preferred in a range of 0.4 to 1.2 eV. Such bandgaps are typical for semiconductor materials.

The semiconductor platelets have a solid constitution with a low or without porosity in it's inner structure. The porosity as determined by mercury porosity measurements is either essentially zero or cannot be determined at all because of the lack of porosity. The effect pigments are preferably produced by PVD methods. Their main surfaces (top and below) are rather flat and smooth as typical for PVD effect pigments. Such smooth structures and the absence of noticeable inner porosity enable the platelets to act with optimal reflectance.

Due to the high refractive index of these materials in the visible wavelength region the platelet semiconductor particles exhibit a rather strong reflection. Depending on the thickness of the semiconductor platelets various colors may be produced.

Accordingly the average thickness tₐ of the single semiconductor platelet is preferably in a range of 5 to 160 nm, more preferably in a range of 10 to less than 140 nm and most preferably in a range of 15 to 130 nm. With “average thickness” the arithmetical mean of a sample of pigment thickness' is meant.

Above an average thickness tₐ of 160 nm the platelet semiconductor might not be well oriented in the final coating system and the hiding power is reduced significantly. Below 5 nm of the average thickness tₐ the platelets may become mechanically unstable and may be difficult to be reproduced in sufficient quality.

The tₐ-value is determined by counting the thickness distribution of the platelets using SEM as described in WO 2004087816 A2 except that the arithmetical mean is determined instead of the median value.

In preferred embodiments the flaky effect pigments have a silvery appearance with an average thickness tₐ of the single semiconductor platelet in a range of 12 to 40 nm and preferably in a range of 18 to 35 nm. Especially preferred for such kind of flaky effect pigments are Si—Ge or Si—Sn alloys as previously described.

With a “silvery appearance” or a “neutral color tone” it is meant in this invention that in an application of these effect pigments a color neutral chroma effect over all measured angles (−15°, 15°, 25°, 45°, 75° and) 110° which is achieved when the absolute values of the a*- and b*-values are independently to be less than 6.5, more preferably less than 4.0 and most preferably less than 2.0 units in the CIELab color space. Preferably the application as described in the draw-down in the experimental section are used here.

In other preferred embodiments the flaky effect pigment has a colored appearance with a median thickness h₅₀ of the single semiconductor platelet in a range of larger than 40 to 160 nm. Here the absolute values of the a*- and b*-values range independently are equal or more than 6.5 units in the CIELab color space.

Regarding the sizes and size distributions of the flaky effect pigments typical size ranges of coatings in the automotive industry or of industrial coatings are chosen. Preferably the flaky effect pigment have a d₅₀ of the particle size distribution is in a range of 2 to 100 μm, more preferably in a range of 5 to 40 μm, further more preferred in a range of 6 to 35 μm and most preferably in a range of 7 to 30 μm.

The pigment size is typically indicated using quantiles (d values) from the volume averaged particle size distribution. Here, the number indicates the percentage of particles smaller than a specified size contained in a volume-averaged particle size distribution. For example, the d₅₀ value indicates the size where 50% of the particles are smaller than this value. These measurements are conducted e.g. by means of laser granulometry using a particle size analyzer manufactured by Horiba and is a Horiba LA 950 instrument. The measurements are conducted using Fraunhofer approximation for equivalent spheres and suitable parameters according to informations from the manufacturer.

The d₁₀-values characterize the amount of fine particles and typically range from 2 to 20 μm and preferably from 4 to 15 μm.

The d₉₀-values characterize the amount of coarse particles and typically range from 15 μm to 140 μm and preferably from 20 μm to 50 μm.

The width of the particle size distribution can be characterized by the span defined as (d₉₀-d₁₀)/d₅₀ and preferably this span is in a range of 1.50 to 2.2 and more preferably in a range of 1.6 to 2.0.

Without being bound to a certain theory the inventors think that due to the fact that the particle sizes of the effect pigments are much smaller than the radar microwaves the attenuation of radar wave is even lower than in macroscopic films of the corresponding semiconductor materials.

The flaky effect pigments according to this invention preferably have an aspect ratio defined as d₅₀/h₅₀ in a range of 30 to 2000, more preferred in a range of 40 to 1500 and most preferred in a range of 50 to 1000.

Within this invention the only optically active layer of the flaky effect pigments consist of the semiconductor platelet described before. A further advantage of these effect pigments compared to metal flakes, especially to widely used aluminum flakes is their excellent gassing stability. Usually these platelets do not need to be coated with further corrosion inhibition layers.

However, in some cases such coatings might be necessary. More often, certain coatings with optically non-active materials might be useful.

Therefore, in further embodiments the single semiconductor platelet is further encapsulated with transparent not optically active metal oxides of refractive index n<1.8, preferably a refractive index of <1.6.

With an optically non-active layer it is meant within this invention a layer which reflects less than 20% or preferably less than 10% of incoming light in the visible wavelengths region. Additionally it does not change the chroma response. Particularly, an outer optical non-active layer will exhibit a change of such coated effect pigment compared to the same layer stack effect pigment without an outer non-active layer when applicated in a nitrocellulose lacquer as described in the experimental section of a ΔC*_{15°} of ≤2.0 and/or a ΔH*_{15°} of ≤10° and preferably ≤ 5° and/or a ΔL*_{15°} of ≤10.

Typically such non-active layers have a mean refractive index in the visible wavelength region of less than 1.7, more preferably less than 1.6. Typically such non-active layers have an optical density of less than 34 nm and more preferably less than 32 nm in the visible wavelength region. Herein, the refractive index refers to literature bulk values of the respective material rather than the effective refractive index of the layer.

In preferred embodiments the optically non-active layer encapsulates essentially the whole semiconductor platelet and consists of a layer of Mo-oxide, SiO₂, Al₂O₃, B₂O₃ or mixtures thereof. If not used for further enhancing gassing stability a typical optically non-active layer are surface modifiers like organofunctional silanes, titanates, aluminates or zirconates, phosphate ester, phosphonate esters, phosphite esters, alcohol or amine based additives and combinations thereof. Such surface modifiers are used as top-coating to adjust the chemical compatibility of the effect pigment to the binder medium of the final application as described in e.g. EP 1084198 A1. They can be coated either directly on the single semiconductor platelet pigment or on the optically non-active layer. Most preferred as surface modifiers are organofunctional silanes. In another preferred embodiment the semiconductor platelet is coated first by a thin layer od SiO₂ and then coated with suitable surface modifiers, most preferably organofunctional silanes. The SiO₂ layer here is primarily used to enhance the adhesion of the organofunctional silanes to the surface of the semiconductor platelet.

Suitable organofunctional silanes are available commercially and are produced, for example, by Evonik, Rheinfelden, Germany and sold under the trade name “Dynasylan®”. Further products can be purchased from OSi Specialties (Silquest® silanes) or from Wacker (Genosil® silanes).

Examples of suitable organofunctional silanes are 3-methacryloxypropyl trimethoxy silane (Dynasylan MEMO), vinyl tri (m) ethoxy silane (Dynasylan VTMO or VTEO), 3-mercaptopropyl tri (m) ethoxy silane (Dynasylan MTMO or 3201), 3-glycidyloxypropyl trimethoxy silane (Dynasylan GLYMO), tris(3-trimethoxysilylpropyl) isocyanurate (Silquest Y-11597), gamma-mercaptopropyl trimethoxy silane (Silquest A-189), bis(3-triethoxysilylpropyl) polysulfide (Silquest A-1289), bis(3-triethoxysilyl) disulfide (Silquest A-1589), beta (3,4-epoxycyclohexyl) ethyltri-methoxysilane (Silquest A-186), gamma-isocyanatopropyl-trimethoxsilane (Silquest A-Link 35, Genosil GF40), (methacryloyloxymethyl) trimethoxysilane (Genosil XL 33) and (isocyanatomethyl)trimethoxysilane (Genosil XL 43).

In one preferred embodiment the organofunctional silane mixture that modifies the SiO₂ layer comprises at least one amino-functional silane. The amino function is a functional group which is able to enter into chemical interactions with the majority of groups present in binders. This interaction may involve a covalent bond, such as with isocyanate or carboxylate functions of the binder, for example, or hydrogen bonds such as with OH or COOR functions, or else ionic interactions. It is therefore very highly suitable for the purpose of the chemical attachment of the effect pigment to different kinds of binder.

The following compounds are employed preferably for this purpose:
aminopropyl trimethoxy silane (Dynasylan AMMO), aminopropyl triethoxy silane (Dynasylan AMEO), N-(2-aminoethyl)-3-aminopropyl trimethoxy silane (Dynasylan DAMO), N-(2-aminoethyl)-3-aminopropyl triethoxy silane, triamino-functional trimethoxy silane (Silquest A-1130), bis(gamma-trimethoxysilylpropyl) amine (Silquest A-1170), N-ethyl-gamma-aminoisobutyl trimethoxy silane (Silquest A-Link 15), N-phenyl-gamma-diaminopropyl trimethoxy silane (Silquest Y-9669), 4-amino-3,3-dimethylbutyltrimethoxy-silane (Silquest Y-11637), (N-cyclohexylaminomethyl)-triethoxy silane (Genosil XL 926), (N-phenylaminomethyl)-trimethoxy silane (Genosil XL 973) and mixtures thereof. In another embodiment pre-hydrolysed and pre-condensated organofunctional silanes may be used as described in EP 3080209 B1.

### Method of Manufacturing the Flaky Effect Pigment:

A method of manufacturing the flaky effect pigment comprises the steps:
a) providing a flexible substrate coated with a release agent,
b) evaporating under ultra high vacuum conditions a semiconductor material with a band gap in a range of 0.1 to 2.5 eV and having an average atomic composition of:
   a) Si₍₁₋ₓ₎Geₓ, wherein 0<x<1.00 or
   b) Si_{(1-y)}Sn_{y}, wherein 0<y<0.90 or
   c) Ge_{(1-z)}Sn_{z}, wherein 0<z≤0.60 or
   d) Si₍₁₋ₘ₋ₙ₎GeₘSnₙ, wherein 0<m<1.00, 0<n<1.00
with the provisos that x<1.00; y<1.00, z<1.00 and m+n<1.00, onto the flexible substrate a),
c) stripping the semiconductor film from the flexible substrate in a suitable solvent and comminuting the particles in the dispersion to obtain semiconductor flakes,
d) separating the semiconductor flakes from the solvent and
e) optionally conducting further steps like any of further size classifying of the semiconductor flakes or dispersing the semiconductor flakes in a different solvent and further surface treatment steps.

Step a): This step is conducted essentially in the same manner than known from the manufacture of PVD metal pigments, especially aluminum effect pigments. The flexible substrate is usually a webb made from polymers and most preferably a PET polymer. As release agents those common in the art can be used. Usually the release agents are polymers like for example acrylics, methacrylic or polasterol. They can be also other organic materials as described in US 2004/0131776 A1 or in US20100062244 A1.

In a preferred embodiment step b) is done by a roll-to-roll process. In step b) in one embodiment semiconductor alloys of a predetermined composition are used as bulk materials which are evaporated by suitable means to produce respective gas molecules which are transferred to the flexible substrate coated with a release layer under ultra high vacuum conditions. In another embodiment two or three suitable bulk semiconductor materials of a predetermined purity are used wherein their vapor clouds are allowed to overlap before reaching the substrate.

Step b) can be conducted as an electron beam process, magneton sputtering, resistive evaporation or inductive heating. Most preferred is evaporation of the semiconductor bulk material by an electron beam process.

Steps c), d) and e) are again well known in the art.

Another embodiment of the present invention is concerned with a coating system comprising a binder and the flaky effect pigments of this invention. The binder systems can be acrylics, polyesters, polyurethanes, polyepoxides and copolymers from these. Preferably the coating systems are automotive basic coats.

Such coating system additionally can also comprise other pigments like color pigments, pearlescent pigments or metal effect pigments.

Furthermore the coating systems comprise solvents or solvent mixtures. Preferably they are water-based coating systems. Additionally they may contain fillers or additives as common in the art.

The effect pigment volume concentration in such coatings is preferably 0.1 to 100%, more preferably 1 to 20% and most preferably 1.5 to 15%.

### Further Aspects

The electromagnetic attenuation at specific frequencies (attn) attributed directly to a pigment or coating (pigment and binder) may be calculated by subtracting the measured electromagnetic attenuation of the substrate or substrate and binder from that of the fully coated system including the substrate, binder, and pigment. For simplicity, attn is reported herein in units of decibels (dB). We define the brightness to attenuation ratio as L*15/attn, where attn is the attenuation in dB at a specific electromagnetic frequency or frequency range, such as IR, microwave, and radio frequency. Further aspects of the effect pigments of this invention are as follows:
Aspect 1: A coating system comprising the flaky pigment which comprises as optical active layer a single platelet consisting of a semiconductor material with a band gap in a range of 0.1 to 2.5 eV and having an average atomic composition of:
   a) Si₍₁₋ₓ₎Geₓ, wherein 0<x<1.00 or
   b) Si_{(1-y)}Sn_{y}, wherein 0<y<0.90 or
   c) Ge_{(1-z)}Sn_{z}, wherein 0<z≤0.60 or
   d) Si₍₁₋ₘ₋ₙ₎GeₘSnₙ, wherein 0<m<1.00, 0<n<1.00
with the provisos that x<1.00; y<1.00, z<1.00 and m+n<1.00.
wherein the flaky pigment or coating including the flaky pigment attributes less than 5 dB, preferably less than 4 dB, and most preferably less than 3 dB of attenuation in the frequency range of 0.3 THz-300 THz (IR).
Aspect 2: A coating system comprising the flaky pigment wherein the flaky pigment or coating including the flaky pigment displays a brightness of >85 and a brightness to attenuation ratio of greater than 15, preferably greater than 25, and most preferably greater than 50 in the frequency range of 0.3 THz-300 THz (IR).
Aspect 3: A coating system comprising the flaky pigment wherein the flaky pigment or coating including the flaky pigment attributes less than 3 dB, preferably less than 2 dB, and most preferably less than 1 dB of attenuation in the frequency range of 3-300 GHz (microwave).
Aspect 4: A coating system comprising the flaky pigment wherein the flaky pigment or coating including the flaky pigment displays a brightness of >85 and a brightness to attenuation ratio of greater than 25, preferably greater than 50, and most preferably greater than 100 in the frequency range of 3-300 GHz (microwave).
Aspect 5: A coating system comprising the flaky pigment wherein the flaky pigment or coating including the flaky pigment attributes less than 3 dB, preferably less than 2 dB, and most preferably less than 1 dB of attenuation in the frequency range of 23-79 GHZ (RADAR, subset of microwave).
Aspect 6: A coating system comprising the flaky pigment wherein the flaky pigment or coating including the flaky pigment displays a brightness of >85 and a brightness to attenuation ratio of greater than 25, preferably greater than 50, and most preferably greater than 100 in the frequency range of 23-79 GHZ (RADAR, subset of microwave).
Aspect 7: A coating system comprising the flaky pigment wherein the flaky pigment or coating including the flaky pigment attributes less than 3 dB, preferably less than 2 dB, and most preferably less than 1 dB of attenuation in the frequency range of 0.3 MHz to 3 GHZ (RF).
Aspect 8: A coating system comprising the flaky pigment wherein the flaky pigment or coating including the flaky pigment displays a brightness of >85 and a brightness to attenuation ratio of greater than 25, preferably greater than 50, and most preferably greater than 100 in the frequency range of 0.3 MHz to 3 GHZ (RF).
Aspect 9: A coating system comprising the flaky pigment, wherein the single platelet semiconductor has an average atomic composition of:
   a) Si₍₁₋ₓ₎Geₓ, wherein 0.01<x≤0.9 and preferably 0.02≤x≤0.8 or
   b) Si_{(1-y)}Sn_{y}, wherein 0.02≤y≤0.75 or
   c) Ge_{(1-z)}Sn_{z}, wherein 0.02≤z≤0.5 or
   d) Si₍₁₋ₘ₋ₙ₎GeₘSnₙ, wherein 0.02≤m≤0.8, 0.02≤n≤0.75
Aspect 10: A coating system comprising the flaky pigment, wherein the single platelet semiconductor has an average atomic composition of:
   a) Si₍₁₋ₓ₎Geₓ, wherein 0.05≤x≤0.65 or
   b) Si_{(1-y)}Sn_{y}, wherein 0.05≤y≤0.55 or
   c) Ge_{(1-z)}Sn_{z}, wherein 0.05≤z≤0.4 or
   d) Si₍₁₋ₘ₋ₙ₎GeₘSnₙ, wherein 0.05≤m≤0.65, 0.05≤n≤0.55.

### EXAMPLES

### Comparative Example 1

Commercially available Metalure Liquid Black (Eckart GmbH) which is a black PVD metal effect pigment with strong flop properties.

### Comparative Example 2

Commercially available Metalure L-55700 (Eckart GmbH) which is a standard PVD aluminum effect pigment.

### Example 1: Silicon-Germanium Composite

A silicon and germanium blend was deposited on a 30 cm wide clear polyester film coated with a releasing agent using ebeam PVD evaporation. The ebeam source was positioned 36 cm below the web during process and conditions were modified to achieve a silver coloration for the final pigment. The ebeam source accelerating voltage was held at a constant 10 kV throughout the run.

The materials obtained in Example 1 were all stripped from the polyester film and homogenized to a particles size of ˜19 μm (D₅₀ value). Pigments were prepared with a 10 wt. % non-volatile content (NVM) in propyl glycol methyl ether acetate. The average particle thickness tₐ, obtained via SEM analysis, is 23+/−3 nm. The elemental silicon: germanium atomic ratio determined from energy dispersive spectroscopy is 45:55.

Pigment samples were adjusted to 5% NVM with propyl glycol methyl ether acetate for spray application in Deltron DBC500 Color Blender. Spray inks were formulated to target pigment volume concentrations between approximately 1.8 to 2.4%. Samples were applied in duplicate, achieving full coverage within 1-2 coats over polyester film and ABS plastic substrates. Panels were dried at ambient temperature for approximately 30 minutes between coats.

Gloss data were collected using a BYK Micro Tri-gloss meter. Additional optical data were collected using a BYK Mac meter. Optical data were collected on the polyester films on both the frontside (coating side) and backside of the film. The flop was calculated according to the common formula:

$$Flop index = 2.69 \times {( {L}_{15 °}^{⋆} - {L}_{110 °}^{⋆} )}^{1.11} / {{L}_{45 °}^{*}}^{0.86}$$

The results of these measurements are summarised in Tables 1a to d below.

Tables 1a to d: Optical Data Collected from Silicon Germanium Alloy Effect Pigments of Example 1 at Different Binder: Pigment Ratios and Different Substrates.

TABLE 1a

| Wt.-ratio | Panel | Panel | | | | | | |
|---|---|---|---|---|---|---|---|---|
| Binder:Pigment | Side | Type | L*_{-15°} | L*_{15°} | L*_{25°} | L*_{45°} | L*_{75°} | L*_{110°} |
| 12:1 | Front | Polyester | 134.9 | 116.6 | 72.6 | 30.1 | 11.7 | 6.2 |
| 12:1 | Back | Polyester | 128.2 | 113.1 | 72.2 | 31.2 | 12.5 | 6.5 |
| 12:1 | Front | ABS | 134.2 | 117.0 | 73.4 | 31.8 | 12.5 | 6.7 |
| 16:1 | Front | Polyester | 131.0 | 114.9 | 73.9 | 32.9 | 13.3 | 6.9 |
| 16:1 | Back | Polyester | 125.8 | 110.8 | 72.4 | 33.0 | 13.9 | 7.4 |
| 16:1 | Front | ABS | 132.6 | 116.4 | 74.9 | 33.4 | 13.3 | 6.7 |

TABLE 1b

| Wt.-ratio | Panel | Panel | | | | | | |
|---|---|---|---|---|---|---|---|---|
| Binder:Pigment | Side | Type | a*_{-15°} | a*_{15°} | a*_{25°} | a*_{45°} | a*_{75°} | a*_{-15°} |
| 12:1 | Front | Polyester | −0.1 | 0.1 | 1.0 | 1.3 | 1.0 | −0.1 |
| 12:1 | Back | Polyester | −0.8 | −0.4 | 0.8 | 1.4 | 1.0 | −0.8 |
| 12:1 | Front | ABS | −0.5 | −0.2 | 0.8 | 1.2 | 1.0 | −0.5 |
| 16:1 | Front | Polyester | −0.1 | 0.1 | 0.9 | 1.2 | 1.0 | −0.1 |
| 16:1 | Back | Polyester | −0.9 | −0.4 | 0.7 | 1.3 | 1.0 | −0.9 |

TABLE 1c

| Wt.-ratio | Panel | Panel | | | | | | |
|---|---|---|---|---|---|---|---|---|
| Binder:Pigment | Side | Type | b*_{-15°} | b*_{15°} | b*_{25°} | b*_{45°} | b*_{75°} | b*_{110°} |
| 12:1 | Front | Polyester | −0.3 | 1.0 | 2.3 | 2.8 | 2.1 | 1.3 |
| 12:1 | Back | Polyester | 1.9 | 2.7 | 3.3 | 3.1 | 1.6 | 0.3 |
| 12:1 | Front | ABS | −0.8 | 0.0 | 1.9 | 2.6 | 2.2 | 1.5 |
| 16:1 | Front | Polyester | 0.2 | 1.0 | 2.2 | 2.7 | 2.2 | 1.6 |
| 16:1 | Back | Polyester | 1.4 | 2.1 | 2.9 | 2.8 | 1.4 | 0.3 |

TABLE 1d

| Wt.-ratio | | | | | |
|---|---|---|---|---|---|
| Binder:Pigment | Panel Side | Panel Type | Gloss20° | Gloss60° | Flop |
| 12:1 | Front | Polyester | 22 | 69 | 26.6 |
| 12:1 | Back | Polyester | 106 | 140 | 24.9 |
| 12:1 | Front | ABS | 18 | 61 | 25.4 |
| 16:1 | Front | Polyester | 20 | 64 | 24.1 |
| 16:1 | Back | Polyester | 141 | 139 | 22.9 |

### Example 2: Silicon-Germanium Pigment to Binder Ratio Modification

A silicon and germanium blend was deposited on a 30 cm wide clear polyester film coated with a releasing agent using ebeam PVD evaporation. The ebeam source was positioned 36 cm below the web during process and conditions were modified to achieve a silver coloration for the final pigment. The ebeam source accelerating voltage was held at a constant 10 kV throughout the run.

The materials obtained in Example 2 were all stripped from the polyester film and homogenized to a particles size of ˜14 μm (d₅₀ value). Pigments were prepared with a 10 wt. % non-volatile content (NVM) in propyl glycol methyl ether acetate. The average particle thickness tₐ, obtained via SEM analysis, is 29+/−3 nm. The elemental silicon: germanium atomic ratio determined from energy dispersive spectroscopy is 47:53.

A spray application ladder was designed and executed. Multiple spray inks were formulated to pigment volume concentrations calculated between 3-61%, using Deltron DBC500 Color Blender. Metals content was held constant throughout all ink formulations. Samples were applied in duplicate over ABS panel substrate. The entirety of each ink was applied in a single coat to maintain consistent metals distribution throughout all panels. Select panels from each set were clear-coated with Deltron DC4000 and force-dried for an additional 60 minutes at 60° C. Panels were dried at ambient temperature for approximately 30 minutes between coats.

Gloss data were collected using a BYK Micro Tri-gloss meter. Additional optical data were collected using a BYK Mac colorimeter. The results of these measurements are summarised in Table 2 below.

### Tables 2a,b and c: Gloss-, Flop-, L*-, a*- and b* Values for Example 3 at Different Binder: Pigment Ratios

| Wt.-ratio | Clear | Gloss | Gloss | | | | | | | |
|---|---|---|---|---|---|---|---|---|---|---|
| Binder:Pigment | Coat | 20° | 60° | Flop | L*_{-15°} | L*_{15°} | L*_{25°} | L*_{45°} | L*_{75°} | L*_{110°} |
| 5:1 | No | 39 | 94 | 33.1 | 129 | 110 | 61.5 | 22.2 | 7.3 | 3.9 |
| 5:1 | Yes | 99 | 107 | 21.9 | 126 | 113 | 75.7 | 35.4 | 14.3 | 7.6 |
| 7:1 | No | 43 | 96 | 31.2 | 132 | 113 | 65.1 | 24.6 | 8.3 | 4.1 |
| 7:1 | Yes | 99 | 108 | 24 | 129 | 116 | 76.3 | 33.9 | 12.5 | 6.0 |
| 9:1 | No | 30 | 81 | 30.4 | 137 | 118 | 69.6 | 26.8 | 9.3 | 4.5 |
| 9:1 | Yes | 97 | 106 | 23.8 | 131 | 118 | 79 | 35.1 | 12.8 | 5.9 |
| 12:1 | No | 23 | 68 | 26.7 | 136 | 119 | 74.2 | 31.2 | 11.8 | 5.7 |
| 12:1 | Yes | 96 | 104 | 20.1 | 124 | 113 | 79.4 | 39.1 | 16.1 | 8.29 |
| 15:1 | No | 20 | 64 | 24.1 | 134 | 119 | 78.2 | 34.7 | 13.7 | 6.64 |
| 15:1 | Yes | 93 | 102 | 18.8 | 121 | 111 | 80.6 | 41.1 | 17.7 | 9.08 |

TABLE 2b

| Wt.-ratio | Clear | | | | | | |
|---|---|---|---|---|---|---|---|
| Binder:Pigment | Coat | a_{-15°} | a_{15°} | a_{25°} | a_{45°} | a_{75°} | a_{110°} |
| 5:1 | No | −0.35 | 0.1 | 1.45 | 1.56 | 1.11 | 0.42 |
| 5:1 | Yes | −1.78 | −1.2 | −0.12 | 0.4 | 0.52 | 0.31 |
| 7:1 | No | −0.42 | 0.08 | 1.47 | 1.61 | 1.2 | 0.5 |
| 7:1 | Yes | −1.33 | −0.77 | 0.35 | 0.84 | 0.86 | 0.5 |
| 9:1 | No | −0.65 | −0.12 | 1.35 | 1.7 | 1.3 | 0.65 |
| 9:1 | Yes | −0.78 | −0.29 | 0.58 | 1.06 | 1.07 | 0.67 |
| 12:1 | No | −0.68 | −0.21 | 1.12 | 1.63 | 1.42 | 0.83 |
| 12:1 | Yes | −0.73 | −0.22 | 0.56 | 0.99 | 1.05 | 0.84 |
| 15:1 | No | −0.28 | 0.09 | 1.03 | 1.5 | 1.35 | 1.02 |
| 15:1 | Yes | −0.15 | 0.2 | 0.75 | 1.12 | 1.19 | 1.02 |

TABLE 2c

| Wt.-ratio | Clear | | | | | | |
|---|---|---|---|---|---|---|---|
| Binder:Pigment | Coat | b_{-15°} | b_{15°} | b_{25°} | b_{45°} | b_{75°} | b_{110°} |
| 5:1 | No | −2.48 | −0.62 | 2.59 | 3.17 | 1.83 | 0.85 |
| 5:1 | Yes | −0.47 | 0.55 | 1.61 | 1.71 | 1.61 | 1.19 |
| 7:1 | No | −1.21 | 0.45 | 3.15 | 3.4 | 2.31 | 1.03 |
| 7:1 | Yes | 0.5 | 1.43 | 2.42 | 2.5 | 2.22 | 1.41 |
| 9:1 | No | −0.32 | 1.05 | 3.25 | 3.66 | 2.67 | 1.24 |
| 9:1 | Yes | 2.43 | 2.77 | 3.06 | 2.86 | 2.56 | 1.64 |
| 12:1 | No | 0.21 | 1.23 | 3.05 | 3.51 | 2.76 | 1.7 |
| 12:1 | Yes | 2.59 | 2.89 | 3.11 | 2.85 | 2.52 | 2.16 |
| 15:1 | No | 1.54 | 2.11 | 3.01 | 3.29 | 2.79 | 1.96 |
| 15:1 | Yes | 3.32 | 3.29 | 3.29 | 2.95 | 2.64 | 2.36 |

The effect pigment of this example exhibits rather neutral color tones with high flop values making it look as attractive effect pigment with metallic look.

When increasing the binder/pigment ratio flop and gloss values tend to be reduced as here with reduced binder concentration, there is less spacing between the flakes as the system dries. This ensures that the pigments orient better in a flat/parallel positions relative to the substrate to produce high reflectivity.

### Example Series 3: SiSn

Further samples of silicon alloy flakes were manufactured according to Example 2, but with tin instead of germanium as the alloy material. Three experiments were conducted under different conditions in order to vary the composition and thickness of the resulting alloy flakes. The Si:Sn composition and flake thickness were varied and verified with SEM analysis, as shown in Table 4. In this analysis oxygen contents were excluded.

TABLE 3
Thickness and composition excluding oxygen

| | Si:Sn Atomic | Average |
|---|---|---|
| Sample | Ratio | Thickness (nm) |
| Example 3a | 79:21 | 29 |
| Example 3b | 69:31 | 26 |
| Example 3c | 70:30 | 35 |

Multiple spray inks were formulated with binder: pigment ratios shown in Table 4, using Deltron DBC500 Color Blender. Metals content was held constant throughout all ink formulations. Samples were applied in duplicate over ABS panel substrate. The entirety of each ink was applied in a single coat to maintain consistent metals distribution throughout all panels. Select panels from each set were clear-coated with Deltron DC4000 and force-dried for an additional 60 minutes at 60° C. Panels were dried at ambient temperature for approximately 30 minutes between coats.

Gloss data were collected using a BYK Micro Tri-gloss meter. Additional optical data were collected using a BYK Mac colorimeter. The results of these measurements are summarised in Table 4 below. Data of the Comparative Examples 1 (Commercially available Metalure Liquid Black) and 2 (Commercially available Metalure L-55700) are shown for comparison.

Tables 4a to c: Optical Data from Silicon Tin Alloy Effect Pigments of Example 3

TABLE 4a

| | Binder:Pigment | Clear | Gloss | Gloss | | | | | | | |
|---|---|---|---|---|---|---|---|---|---|---|---|
| Sample | ratios | Coat | 20° | 60° | Flop | L*_{-15°} | L*_{15°} | L*_{25°} | L*_{45°} | L*_{75°} | L*_{110°} |
| Ex. 3a | 7:1 | No | 3 | 13 | 16.5 | 133.3 | 110.5 | 83.4 | 45.1 | 20.5 | 12.3 |
| Ex. 3a | 7:1 | Yes | 96 | 98 | 8.29 | 75.0 | 72.5 | 63.3 | 44.8 | 28.7 | 20.0 |
| Ex. 3b | 7:1 | No | 3 | 16 | 17.25 | 133.0 | 110.0 | 81.2 | 43.2 | 19.4 | 11.2 |
| Ex. 3b | 7:1 | Yes | 95 | 98 | 9.08 | 77.9 | 74.6 | 64.0 | 44.0 | 27.2 | 18.5 |
| Ex. 3c | 3.5:1 | No | 14 | 56 | 27.72 | 157.5 | 134.2 | 82.1 | 33.8 | 14.2 | 9.1 |
| Ex. 3c | 3.5:1 | Yes | 99 | 105 | 17.21 | 128.4 | 117.0 | 85.7 | 45.7 | 22.3 | 14.1 |
| Ex. 3c | 7:1 | No | 13 | 50 | 23.65 | 148.8 | 129.0 | 83.4 | 38.0 | 16.8 | 10.2 |
| Ex. 3c | 7:1 | Yes | 98 | 102 | 13.14 | 113.1 | 105.3 | 83.0 | 50.1 | 27.8 | 18.7 |
| Comp. | 7:1 | No | 8 | 37 | 18.26 | 116.6 | 101.3 | 70.3 | 36.8 | 17.4 | 9.6 |
| Ex. 1 | | | | | | | | | | | |
| Comp. | 7:1 | Yes | 95 | 98 | 9.9 | 79.6 | 75.4 | 63.2 | 42.4 | 25.49 | 16.6 |
| Ex. 1 | | | | | | | | | | | |
| Comp. | 7:1 | No | 37 | 104 | 26.0 | 187.0 | 161.4 | 98.8 | 42.7 | 23.24 | 20.0 |
| Ex. 2 | | | | | | | | | | | |
| Comp. | 7:1 | Yes | 105 | 120 | 19.2 | 172.3 | 154.9 | 109.3 | 54.7 | 29.2 | 24.3 |
| Ex. 2 | | | | | | | | | | | |

TABLE 4b

| | Binder:Pigment | Clear | | | | | | |
|---|---|---|---|---|---|---|---|---|
| Sample | ratios | Coat | a*_{-15°} | a*_{15°} | a*_{25°} | a*_{45°} | a*_{75°} | a*_{110°} |
| Ex. 3a | 7:1 | No | −1.27 | −1.19 | −0.84 | −0.13 | 0.61 | 0.69 |
| Ex. 3a | 7:1 | Yes | −1.22 | −1.07 | −0.84 | −0.4 | −0.14 | −0.1 |
| Ex. 3b | 7:1 | No | −0.91 | −0.89 | −0.75 | −0.38 | 0.08 | 0.2 |
| Ex. 3b | 7:1 | Yes | −1.69 | −1.51 | −1.25 | −0.74 | −0.38 | −0.27 |
| Ex. 3c | 3.5:1 | No | −0.57 | −0.21 | 0.13 | 0.36 | 0.4 | 0.34 |
| Ex. 3c | 3.5:1 | Yes | −0.34 | −0.06 | 0.08 | 0.21 | 0.25 | 0.24 |
| Ex. 3c | 7:1 | No | 0.32 | 0.46 | 0.62 | 0.57 | 0.53 | 0.46 |
| Ex. 3c | 7:1 | Yes | 0.5 | 0.61 | 0.54 | 0.41 | 0.37 | 0.35 |
| Comp. | 7:1 | No | −1.28 | −1.2 | −0.88 | −0.54 | −0.32 | −0.28 |
| Ex. 1 | | | | | | | | |
| Comp. | 7:1 | Yes | −1.34 | −1.19 | −1.06 | −0.78 | −0.59 | −0.51 |
| Ex. 1 | | | | | | | | |
| Comp. | 7:1 | No | −1.00 | −0.58 | −0.02 | 0.2 | 0.13 | −0.04 |
| Ex. 2 | | | | | | | | |
| Comp. | 7:1 | Yes | −1.37 | −0.92 | −0.6 | −0.29 | −0.21 | −0.49 |
| Ex. 2 | | | | | | | | |

TABLE 4c

| | Binder:Pigment | Clear | | | | | | |
|---|---|---|---|---|---|---|---|---|
| Sample | ratios | Coat | b*_{-15°} | b*_{15°} | b*_{25°} | b*_{45°} | b*_{75°} | b*_{110°} |
| Ex. 3a | 7:1 | No | −0.78 | −0.42 | −0.11 | 0.71 | 1.93 | 2.05 |
| Ex. 3a | 7:1 | Yes | 0.23 | 0.40 | 0.67 | 0.94 | 1.23 | 1.19 |
| Ex. 3b | 7:1 | No | −0.38 | −0.31 | −0.4 | −0.08 | 0.61 | 0.74 |
| Ex. 3b | 7:1 | Yes | −1.02 | −0.86 | −0.66 | −0.29 | 0.23 | 0.32 |
| Ex. 3c | 3.5:1 | No | 3.85 | 4.73 | 3.52 | 2.36 | 1.64 | 1.45 |
| Ex. 3c | 3.5:1 | Yes | 5.55 | 5.27 | 4.02 | 2.46 | 1.73 | 1.57 |
| Ex. 3c | 7:1 | No | 4.48 | 4.71 | 3.78 | 2.51 | 1.82 | 1.73 |
| Ex. 3c | 7:1 | Yes | 6.22 | 5.77 | 4.62 | 2.94 | 2.13 | 1.99 |
| Comp. | 7:1 | No | −0.96 | −0.76 | −0.32 | −0.12 | 0.09 | 0.2 |
| Ex. 1 | | | | | | | | |
| Comp. | 7:1 | Yes | 0.26 | 0.19 | 0.18 | −0.05 | 0.03 | 0.03 |
| Ex. 1 | | | | | | | | |
| Comp. | 7:1 | No | −2.09 | −1.41 | −0.25 | 1 | 0.44 | 0.58 |
| Ex. 2 | | | | | | | | |
| Comp. | 7:1 | Yes | −0.68 | −0.5 | −0.63 | 0.14 | 0.17 | 0.1 |
| Ex. 2 | | | | | | | | |

From Table 4a it can be well seen that the inventive examples have a flop in between Comparative Example 1 (Metalure Liquid Black) and Comparative Example 2 (standard PVD aluminum pigment). The a*-, b*-values are small and show an essentially neutral color tone. Visually the effect pigments appear as silvery color tones with strong lightness flop.

### Examples 4a,b: SiGe and SiSn Extended Testing

Samples of an silicon germanium and silicon tin alloy flakes were manufactured according to parameters outlined in Examples 1-3, but with slightly different compositions. The materials obtained in Example 4 were stripped from their polyester films and homogenized to particle sizes of 12-15 μm (d₅₀ value). Pigment dispersions were prepared with a 10 wt. % non-volatile content (NVM) in propyl glycol methyl ether. The SEM/EDX analysis revealed alloy compositions of Si₄₆Ge₅₄ and Si₆₆Sn₃₄, respectively. The average particle thickness (tₐ) for the SiGe and SiSn alloys were found to be 28+/−3 nm and 29+/−3 nm, respectively. In this analysis oxygen contents were excluded.

A binder formulation was made by mixing and stirring 43.5 parts of NC E 1160 (from Hagederon AG, Germany) binder in isopropyl 30, with 9 wt.-% binder content in butyl acetate 85 together with 26.5 parts butyl acetate, 26.5 part xylol, 0.6 parts butyl diglycol, 1.6 parts butyl glycol to which 0.3 parts of Byk 358 N and 1.0 part of Byk 120 were added as additives.

Multiple spray inks were formulated with binder: pigment ratios shown in Table 5. Viscosity was adjusted using a 1:1 solvent mixture of butyl acetate and xylol. Spray inks were applied to ABS panels using a spray-coating apparatus APL 3.3 from Company Oerter, Germany. Each formulation was sprayed four times to achieve full-tone coverage of each effect pigment.

The radar transparency measurements were done with microwave radiation with a frequency of 76.5 GHz using as a measurement system an RMS-D-77/79G apparatus from Perisens GmbH, Germany. Additional optical data were collected using a BYK Mac colorimeter.

Radar attenuation and optical results of the sprayed panels are shown in Table 5. Radar data has been background corrected to account for loss produced by the uncoated substrate.

Tables 5a,b,c: Radar and Optical Characterization of Example 3 Against Comp. Examples

TABLE 5a

| | | Attenuation/ | | | | | | | |
|---|---|---|---|---|---|---|---|---|---|
| | | Radar Loss | | | | | | | |
| | | (dB), | | | | | | | |
| | Wt.-ratio | Background | | | | | | | |
| Sample | Binder:Pigment | corrected | Flop | L*_{-15°} | L*_{15°} | L*_{25°} | L*_{45°} | L*_{75°} | L*_{110°} |
| Example 4a | 3.8:1 | ~0 | 30.1 | 110.1 | 89.3 | 48.3 | 18.7 | 7.7 | 4.2 |
| (SiGe) | | | | | | | | | |
| Example 4b | 4.2:1 | 0.07 | 42.1 | 132.15 | 113.58 | 72.88 | 34.54 | 16.45 | 9.96 |
| (SiSn) | | | | | | | | | |
| Comp. | 4.5:1 | 1.55 | 37.0 | 101.9 | 82.4 | 42.2 | 13.6 | 4.30 | 2.30 |
| Example 1 | | | | | | | | | |
| Comp. | 4.5:1 | 2.15 | 24.8 | 155.5 | 129.3 | 74.0 | 33.4 | 20.5 | 17.2 |
| Example 2 | | | | | | | | | |

TABLE 5b

| | Wt. % ratio | | | | | | |
|---|---|---|---|---|---|---|---|
| Sample | Binder:Pigment | a*_{-15°} | a*_{15°} | a*_{25°} | a*_{45°} | a*_{75°} | a*_{110°} |
| Example 4a | 3.8:1 | 2.77 | 2.57 | 2.33 | 1.31 | 0.96 | 0.46 |
| (SiGe) | | | | | | | |
| Example 4b | 4.2:1 | −1.20 | −1.19 | −0.48 | −0.15 | −0.04 | 0.05 |
| (SiSn) | | | | | | | |
| Comp. | 4.5:1 | −0.74 | −0.09 | 0.05 | 0.06 | 0.05 | −0.74 |
| Example 1 | | | | | | | |
| Comp. | 4.5:1 | −0.47 | 0.33 | 0.44 | 0.41 | 0.31 | −0.47 |
| Example 2 | | | | | | | |

TABLE 5c

| | Wt. % ratio | | | | | | |
|---|---|---|---|---|---|---|---|
| Sample | Binder:Pigment | b*_{-15°} | b*_{15°} | b*_{25°} | b*_{45°} | b*_{75°} | b*_{110°} |
| Example 4a | 3.8:1 | 2.77 | 2.57 | 2.33 | 1.31 | 0.96 | 0.84 |
| (SiGe) | | | | | | | |
| Example 4b | 4.2:1 | 6.59 | 6.58 | 4.89 | 2.73 | 1.67 | 0.29 |
| (SiSn) | | | | | | | |
| Comp. | 4.5:1 | −1.98 | −1.39 | −0.64 | −0.27 | 0.20 | 0.12 |
| Example 1 | | | | | | | |
| Comp. | 4.5:1 | 1.25 | 1.2 | 1.33 | 0.82 | 0.29 | 1.55 |
| Example 2 | | | | | | | |

It can be well seen that the silicon germanium and silicon tin alloy effect pigments produce a radar attenuation of essentially zero, while both metal effect pigments display significant losses. All applications were realized with full hiding power of the effect pigments.

When compared in full-tone hiding, the optical flop exhibited by the effect pigment alloys of Example 4 is comparable to that of the effect pigments of Comparative Examples 1 and 2. The L*15 value, typically considered a brightness indicator, is between Comparative Example 1 and 2.

Examples 5: SiGe, and SiSn and Comparative Examples 3: Si Further samples of silicon-germanium and silicon-tin alloy flakes were manufactured according to Examples 1-3. Additional comparative Si-only samples were manufactured with varying silicon thicknesses. The Si:Ge, Si:Sn, and Si composition and average particle thickness (tₐ) were verified with SEM analysis, as shown in Table 6. Oxygen contents were excluded in this analysis.

The deposited materials were all stripped from the polyester film and homogenized to a particles size of 12-15 μm (d₅₀ value). Inks were prepared in an Eckart's in-house binder system, composed of Hagedorn H7 Nitrocellulose binder (obtainable from Hagedorn AG, Osnabrück, Germany) in a solvent blend of ethyl acetate and propylene glycol methoxy ether. Formulations were based on a 1.85:1 weight ratio of binder to metal content with a 1.5% total metal content. The samples were drawn down on a flat polyester film with a wire wound rod to a 40 μm wetfilm thickness.

Gloss and color data were collected from the reverse side of each polyester film using a BYK Micro Tri-gloss meter and BYK Mac colorimeter, respectively. Opacity data were collected using an X-rite 341C transmission densitometer by averaging 6 collection points along the coated polyester film. The results of these measurements are summarised in Table 6. Data of the Comparative examples 1 (Commercially available Metalure Liquid Black) and 2 (Commercially available Metalure L-55700) are shown for comparison.

Tables 6a,b: Optical, Thickness, and Compositional Data from Effect Pigments of Example 5 and Comparative Examples.

| | ta | Si | Ge/Sn | Opacity | | |
|---|---|---|---|---|---|---|
| Sample | (nm) | at % | at % | (OD) | G20° | G60° |
| Ex. 5a | 27 | 43 | 57 | 1.58 | 280 | 209 |
| (SiGe) | | | | | | |
| Ex. 5b | 29 | 67 | 34 | 1.56 | 258 | 200 |
| (SiSn) | | | | | | |
| Comp. | 27 | 100 | 0 | 0.47 | 206 | 172 |
| Ex. 3a | | | | | | |
| (Si) | | | | | | |
| Comp. | 29 | 100 | 0 | 0.53 | 195 | 170 |
| Ex. 3b | | | | | | |
| (Si) | | | | | | |
| Comp. | 31 | 100 | 0 | 0.57 | 207 | 182 |
| Ex. 3c | | | | | | |
| (Si) | | | | | | |
| Comp. | N/A | — | — | 1.39 | 201 | 177 |
| Ex. 1 | | | | | | |
| Comp. | N/A | — | — | 2.96 | 430 | 334 |
| Ex. 2 | | | | | | |

TABLE 6b

| Sample | C*₋₁₅ | C*₁₅ | C*₂₅ | C*₄₅ | C*₇₅ | C*₁₁₀ |
|---|---|---|---|---|---|---|
| Ex. 5a | 3.10 | 4.63 | 3.53 | 1.76 | 1.24 | 1.34 |
| (SiGe) | | | | | | |
| Ex. 5b | 2.40 | 1.24 | 1.36 | 2.42 | 0.49 | 1.00 |
| (SiSn) | | | | | | |
| Comp. | 28.56 | 27.05 | 18.5 | 9.5 | 6.31 | 4.78 |
| Ex. 3a | | | | | | |
| (Si) | | | | | | |
| Comp. | 23.23 | 23.91 | 17.8 | 9.46 | 6.31 | 4.93 |
| Ex. 3b | | | | | | |
| (Si) | | | | | | |
| Comp. | 24.23 | 23.12 | 14.81 | 6.99 | 4.31 | 2.98 |
| Ex. 3c | | | | | | |
| (Si) | | | | | | |
| Comp. | 2.29 | 1.48 | 0.63 | 0.14 | 0.59 | 0.88 |
| Ex. 1 | | | | | | |
| Comp. | 2.17 | 1.07 | 0.69 | 0.61 | 0.42 | 1.29 |
| Ex. 2 | | | | | | |

From Tables 6, it can be well seen that the inventive examples display far more neutral color tones as compared to silicon-only samples (Comparative Examples 3) of comparative thickness. Moreover, the SiSn inventive example 5b is nearly as color neutral as the Comparative Example 2 aluminum sample. The gloss values of the inventive examples are also superior to both the silicon-only samples and Comparative Example 1. The opacity values of the inventive examples are also superior to both the silicon-only samples and Comparative Example 1. Thus, color neutrality, gloss, and coverage of the inventive silicon-germanium and silicon-tin alloys are shown to be superior to the silicon-only samples.

1. A flaky effect pigment comprising as the only optical active layer a single platelet consisting of a semiconductor material with a band gap in a range of 0.1 to 2.5 eV, wherein the average thickness tₐ of the single semiconductor platelet is in a range of 5 to 160 nm and having an average atomic composition of:
a) Si₍₁₋ₓ₎Geₓ, wherein 0<x<1.00 or
b) Si_{(1-y)}Sn_{y}, wherein 0<y<0.90 or
c) Ge_{(1-z)}Sn_{z}, wherein 0<z≤0.60 or
d) Si₍₁₋ₘ₋ₙ₎GeₘSnₙ, wherein 0<m<1.00, 0<n<1.00 with the provisos that x<1.00; y<1.00, z<1.00 and m+n<1.00.

2. The flaky effect pigment according to claim 1, wherein the band gap is in a range of 0.2 to 1.4 eV.

3. The flaky effect pigment according to claim 1, wherein the single platelet semiconductor has an average atomic composition of:
a) Si₍₁₋ₓ₎Geₓ, wherein 0.01<x<0.9 or
b) Si_{(1-y)}Sn_{y}, wherein 0.02≤y≤0.75 or
c) Ge_{(1-z)}Sn_{z}, wherein 0.02≤z≤0.5 or
d) Si₍₁₋ₘ₋ₙ₎GeₘSnₙ, wherein 0.02≤m≤0.8, 0.02≤n≤0.75

4. The flaky effect pigment according to claim 1, wherein the single platelet semiconductor has an average atomic composition of:
a) Si₍₁₋ₓ₎Geₓ, wherein 0.05≤x≤0.65 or
b) Si_{(1-y)}Sn_{y}, wherein 0.05≤y≤0.55 or
c) Ge_{(1-z)}Sn_{z}, wherein 0.05≤z≤0.4 or
d) Si₍₁₋ₘ₋ₙ₎GeₘSnₙ, wherein 0.05≤m≤0.65, 0.05≤n≤0.55.

5. The flaky effect pigment according to claim 1, wherein the effect pigment has a silvery appearance with an average thickness tₐ of the single semiconductor platelet in a range of 15 to 40 nm.

6. The flaky effect pigment according to claim 1, wherein the effect pigment has a colored appearance with an average thickness tₐ of the single semiconductor platelet in a range of larger than 40 to 160 nm.

7. The flaky effect pigment according to claim 1, wherein the d₅₀ of the particle size distribution is in a range of 2 to 100 μm.

8. The flaky effect pigment according to claim 1, wherein the aspect ratio d₅₀/tₐ is in a range of 30 to 2000.

9. The flaky effect pigment according to claim 1, wherein the single semiconductor platelet is coated or encapsulated with a transparent not optically active metal oxide of refractive index n<1.8.

10. The flaky effect pigment according to claim 1, wherein the effect pigment is further coated with a surface modifier comprising one or more of an organofunctional silane, a titanate, an aluminate, a zirconate, a phosphate ester, a phosphonate ester, and a phosphite ester.

11. A method of manufacturing a flaky effect pigment comprising the steps of:
a) providing a flexible substrate coated with a release agent,
b) evaporating under ultra high vacuum conditions a semiconductor material with a band gap in a range of 0.1 to 2.5 eV onto the flexible substrate a),
c) stripping the semiconductor film from the flexible substrate in a suitable solvent and comminuting the particles in the dispersion to obtain semiconductor flakes, and
d) separating the semiconductor flakes from the solvent;
the resulting flaky effect pigment comprising as the only optical active layer a single platelet consisting of a semiconductor material with a band gap in a range of 0.1 to 2.5 eV, wherein the average thickness tₐ of the single semiconductor platelet is in a range of 5 to 160 nm and having an average atomic composition of:
a) Si₍₁₋ₓ₎Geₓ, wherein 0<x<1.00 or
b) Si_{(1-y)}Sn_{y}, wherein 0<y<0.90 or
c) Ge_{(1-z)}Sn_{z}, wherein 0<z≤0.60 or
d) Si₍₁₋ₘ₋ₙ₎GeₘSnₙ, wherein 0<m<1.00, 0<n<1.00 with the provisos that x<1.00; y<1.00, z<1.00 and m+n<1.00.

12. The method according to claim 11, wherein step b) is done by a roll-to-roll process.

13. The method according to claim 11, wherein step b) is done with an electron beam process.

14. A coating formulation comprising a binder and the flaky effect pigment according to claim 1.

15. (canceled)

16. The flaky effect pigment according to claim 3, wherein the single platelet semiconductor has an average atomic composition of a) Si₍₁₋ₓ₎Geₓ, wherein 0.02≤x≤0.8.

17. The flaky effect pigment according to claim 9, said metal oxide comprising SiO₂.

18. The method according to claim 11, further comprising further size classifying the semiconductor flakes.

19. The method according to claim 11, further comprising dispersing the semiconductor flakes in a different solvent.

20. The flaky effect pigment according to claim 1, wherein the single platelet semiconductor has an average atomic composition of Si₍₁₋ₓ₎Geₓ, wherein 0<x<1.00.

21. The flaky effect pigment according to claim 1, wherein the single platelet semiconductor has an average atomic composition of Si_{(1-y)}Sn_{y}, wherein 0<y<0.90.
